(19) United States
(12) Patent Application Publication
(10) Pub. No.: US 2025/0309834 A1
(43) Pub. Date: Oct. 2, 2025

(54) POWER AMPLIFIER

(71) Applicant: Taiwan Semiconductor Manufacturing Company, Ltd., Hsinchu (TW)

(72) Inventors: Wei Ling Chang, Hsinchu (TW); Ho-Ching Yen, Hsinchu (TW)

(21) Appl. No.: 18/622,356

(22) Filed: Mar. 29, 2024

(51) Int. Cl. H03F 1/56; H03F 3/24; H03F 3/45

(52) U.S. Cl. CPC H03F 1/565; H03F 3/245; H03F 3/45475; H03F 2200/222; H03F 2200/387; H03F 2203/45116

(57) ABSTRACT

A power amplifier is provided. The power amplifier includes an input matching circuit configured to receive an input signal from a signal source. An amplifier circuit is connected to the input matching circuit. The amplifier circuit is configured to receive the input signal from the input matching circuit and amplify the input signal to generate an output signal. An output matching circuit connected to the amplifier circuit. The output matching circuit is configured to receive the output signal from the amplifier circuit and provide the output signal to a load connected to the output matching circuit. A feedback circuit is connected to at least one or the input matching circuit, the amplifier circuit, and the output matching circuit.

### BACKGROUND

A Radio Frequency (RF) power amplifier converts a low power RF signal into a larger signal of high power. Example applications of the RF power amplifier include driving to another high-power source, driving a transmitting antenna, and exciting microwave cavity resonators. Among these applications, driving transmitter antennas is a widely used application. For example, power amplifiers are used commonly in wireless devices to amplify a signal for transmission.

Power amplifiers may include a gain stage to amplify the signal to a desired power level for its output to a load such as an antenna that radiates the amplified signal. Some performance criteria for the power amplifier include high efficiency, high output power compression, good return loss on the input and output, good gain, and good heat dissipation characteristics. A power amplifier having a good performance under a relatively low power supply voltage is desired in some applications such as wireless devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a diagram of a power amplifier with a feedback network in accordance with some embodiments.

FIG. 2 is an example circuit diagram of a power amplifier of FIG. 1 in accordance with some embodiments.

FIG. 3 is diagram of a power amplifier with feedback circuit that includes transmission lines in accordance with some embodiments.

FIG. 4 is diagram of a power amplifier with a feedback circuit that includes series capacitors with shunt resistors in accordance with some embodiments.

FIG. 5 is diagram of a power amplifier with a feedback circuit that includes series capacitors with switch for the match tuning in accordance with some embodiments.

FIG. 6 is diagram illustrating a power amplifier with a feedback circuit that is connected between an output node of an output matching circuit and an input node of an amplifier circuit in accordance with some embodiments.

FIG. 7 is diagram illustrating a power amplifier with a feedback circuit that is connected between an output node of an amplifier circuit and an input node of an input matching circuit in accordance with some embodiments.

FIG. 8 is diagram illustrating a power amplifier with a feedback circuit that is connected between an output node of an output matching circuit and an input node of an input matching circuit in accordance with some embodiments.

FIG. 9 is a diagram illustrating a differential power amplifier with feedback circuits in accordance with some embodiments.

FIG. 10 is a diagram illustrating a differential power amplifier with differential feedback circuit in accordance with some embodiments.

FIG. 11 illustrates a multi-stage power amplifier 300 with a single stage feedback circuit in accordance with some embodiments.

FIG. 12 illustrates a multi-stage power amplifier 300 with multiple feedback circuits in accordance with some embodiments.

FIG. 13 is a flow diagram of a method 400 for amplifying an input signal in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

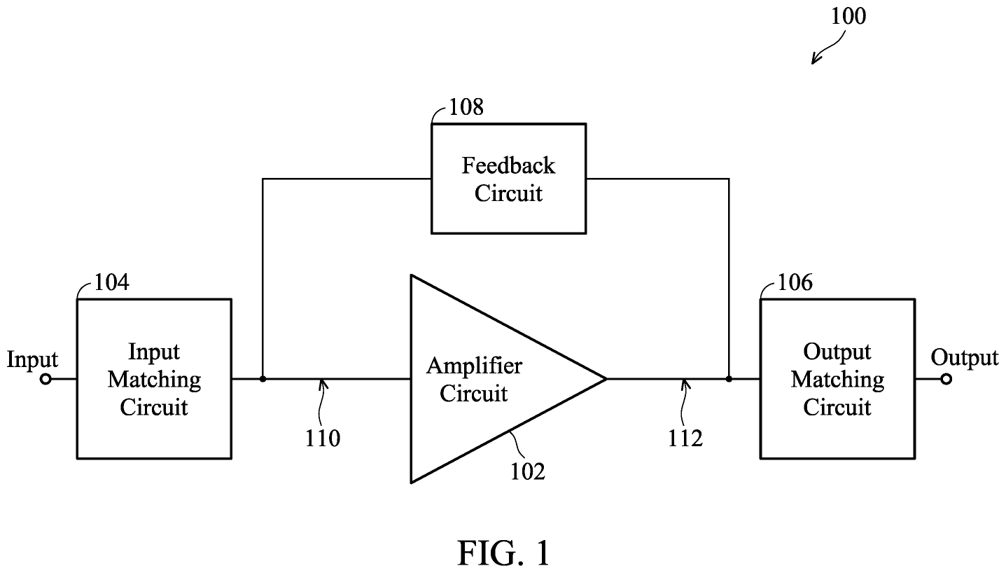

FIG. 1 is a diagram of a power amplifier 100 with a feedback circuit in accordance with some embodiments. Power amplifier 100 receives a first signal or an input signal having a first power at an input terminal as an input. Power amplifier 100 converts the first signal to a second signal or an output signal having a second power. Power amplifier 100 provides the second signal as an output at an output terminal. The second power is higher than the first power.

As shown in FIG. 1, power amplifier 100 includes an amplifier circuit 102 (also referred to as a gain circuit), an input matching circuit 104, an output matching circuit 106, and a feedback circuit 108. An output terminal of input matching circuit 104 is connected to an input terminal of amplifier circuit 102 at a first node 110. An output terminal of amplifier circuit 102 is connected to an input terminal of output matching network 106 at a second node 112. In some examples, first node 110 is an input node of amplifier circuit 102 and second node 112 is an output node of amplifier circuit 102. Feedback circuit 108 is connected between first node 110 and second node 112. Thus, feedback circuit 108 is connected between the output node and the input node of the amplifier circuit 102.

Input matching circuit 104 receives the input signal from a signal source (not shown) and provide the input signal to the input terminal of amplifier circuit 102. In addition, input matching circuit 104 matches an impedance of amplifier circuit 102 (also referred to as an amplifier impedance) with an impedance of a source of the input signal (also referred to as a source impedance). Therefore, input matching circuit 104 minimizes return loss between input matching circuit 104 and the signal source of the input signal.

Power amplifier 102 receives the input signal at its input terminal, amplifies the input signal to generate the output signal, and provides the output signal to output matching circuit 106 through its output terminal. Output matching circuit 106 receives the output signal from amplifier circuit 102 and provides the output signal to an antenna or a load (not shown) through its output terminal. In addition, output matching circuit 106 matches the amplifier impedance with an impedance of the antenna or the load (also referred to as a load impedance). Input matching circuit 104 and output matching circuit 106 are provided minimize return losses and to efficiently transfer signals to and from amplifier circuit 106.

Feedback circuit 108 provides an output conjugate matching between the antenna and the input source. In some examples, feedback circuit 108 compensates for a parasitic impedance of amplifier circuit 102 observed between the input terminal and the output terminal of amplifier circuit 102. In some other examples, in combination with output matching circuit 106, feedback circuit 108 provides the output impedance matching and a reserve isolation. Therefore, feedback circuit 108 improves amplifier efficiency, the reverse isolation, and the output return loss without sacrificing output power performance for power amplifier 100.

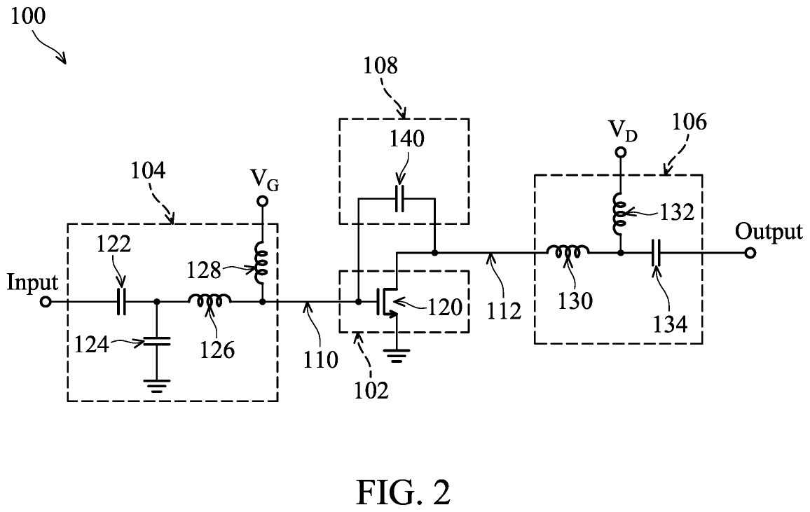

FIG. 2 is an example circuit diagram of power amplifier 100 in accordance with some example embodiments. As shown in FIG. 2, amplifier circuit 102 includes a transistor 120. Although, amplifier circuit 102 is shown to include only one transistor, it can include a more complex circuit with multiple transistors. A gate of transistor 120 is connected to first node 110. A drain of transistor 120 is connected to second node 112 and a source of transistor 120 is connected to the ground. However, transistor 120 is symmetric. That is, the source of transistor 120 can be its drain and vice versa. Transistor 120 is a semiconductor device, for example, a Complementary Metal Oxide Semiconductor (CMOS) transistor, a Silicon on Insulator (SOI) transistor, a Gallium Nitride GaN transistor, etc.

Input matching circuit 104 includes a first energy storage device 122, a second energy storage device 124, a first inductor 126, and a second inductor 128. A first terminal of first energy storage device 122 is the input terminal of power amplifier 100. A second terminal of first energy storage device 122 is connected to a first terminal of first inductor 126. A second terminal of first inductor 126 is connected to first node 110. A first terminal of second energy storage device 124 is connected to the second terminal of first energy storage device 122. Thus, the second terminal of first energy storage device 122, the first terminal of second energy storage device 124, and the first terminal of first inductor 126 are connected to a first common node. A second terminal of second energy storage device 124 is connected to the ground. A first terminal of second inductor 128 is connected to a first reference voltage (also referred to as a gate voltage VG). A second terminal of second inductor 128 is connected to first node 110. In examples, a combined impedance value of first energy storage device 122, second energy storage device 124, first inductor 126, and second inductor 128 may be equal to an output impedance of a source of the input signal at an operating frequency of power amplifier 100. In some examples, first energy storage device 122 and second energy storage device 124 are capacitors.

Output matching circuit 106 includes a third inductor 130, a fourth inductor 132, and a third energy storage device 134. A first terminal of third inductor 130 is connected to second node 112. A second terminal of third inductor 130 is connected to a first terminal of third energy storage device 134. A first terminal of fourth inductor 132 is connected to a second reference voltage (also referred to as a drain voltage V_{D}). A second terminal of fourth inductor 132 is connected to the second terminal of first inductor 130. Thus, the second terminal of third inductor 130, the second terminal of fourth inductor 132, and the first terminal of third energy storage device 134 are connected to a second common node. A second terminal of third energy storage device 134 is the output terminal of power amplifier 100. In examples, a combined impedance value of third inductor 130, fourth inductor 132, and third energy storage device 134 may be equal to an input impedance of a load connected to the output terminal of power amplifier 100 at an operating frequency of power amplifier 100. In some examples, third energy storage device 134 is a capacitor.

Feedback circuit 108 includes a fourth energy storage device 140. A first terminal of fourth energy storage device 140 is connected to first node 110 and a second terminal of fourth energy storage device 140 is connected to second node 112. In some examples, fourth energy storage device 140 is a capacitor. However, and in accordance with example embodiments, feedback circuit 108 may comprise one or more active elements, for example, an inductor, a transmission line, a capacitor, a resistor, a transformer, etc. In accordance with some other embodiments, feedback circuit 108 may include one or more passive elements, for example, a transistor, a diode, etc. In accordance with some other embodiments, feedback circuit 108 may include a combination one or more active elements and one or more passive elements.

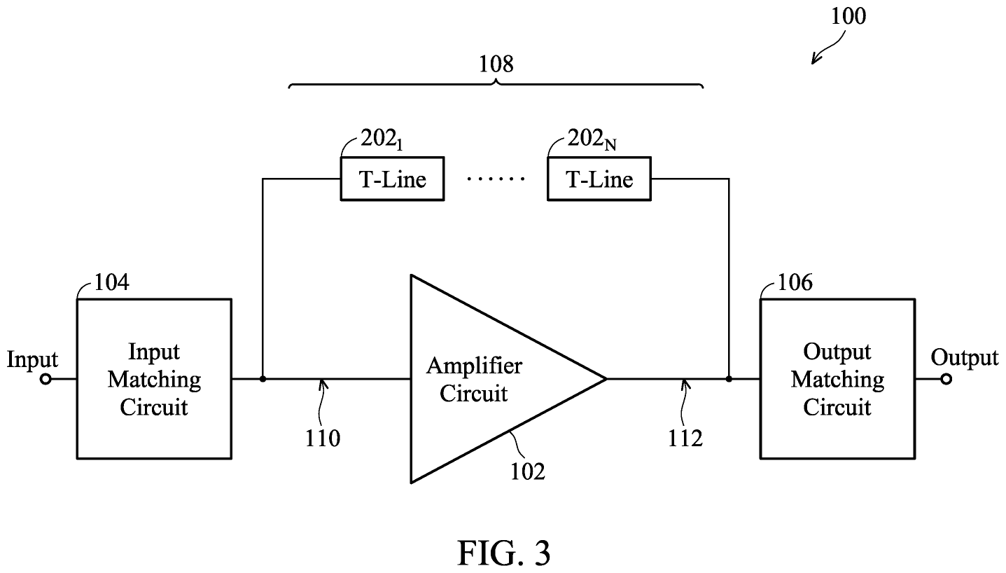

FIG. 3 is diagram of a power amplifier 100 with feedback circuit 108 that includes transmission lines in accordance with some embodiments. As shown in FIG. 3, feedback circuit 108 includes a plurality of transmission lines, for example, a first transmission line 202₁, . . . , and a Nth transmission line 202_{N}. Each transmission line of the plurality of transmission lines are connected in series with one another between first node 110 and second node 112 with a first terminal of first transmission line 202₁ being connected to first node 110 and a second terminal of Nth transmission line 202_{N} being connected to second node 112.

In some examples, the plurality of transmission lines of feedback circuit 108 form a stepped impedance filter that includes a cascaded structure of alternating high and low impedance transmission lines. In some other examples, the plurality of transmission lines form a low pass filter or a slow wave filter. Feedback circuit 108 of FIG. 3 improves impedance matching of power amplifier 100. In some examples, a number of transmission lines of feedback circuit 108 can be varied to vary an impedance of feedback circuit 108.

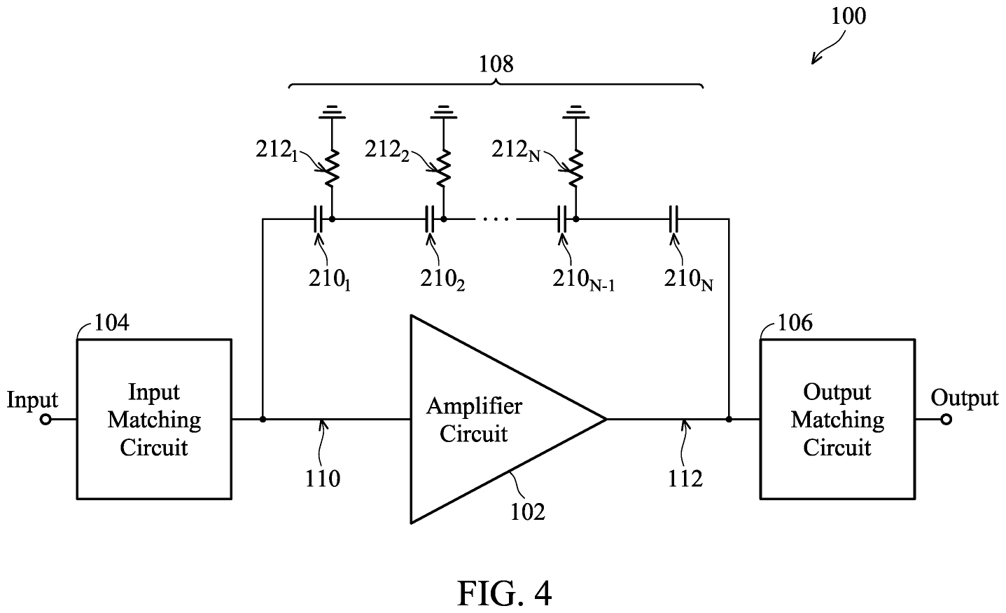

FIG. 4 is diagram of a power amplifier 100 with feedback circuit 108 that includes series capacitors with shunt resistors in accordance with some embodiments. As shown in FIG. 4, feedback circuit 108 includes a plurality of capacitors, for example, a first capacitor 210₁, a second capacitor 210₂, . . . , (N−1)th capacitor 210_{N-1}, and a Nth capacitor 210_{N}. Each capacitor of the plurality of capacitors are connected in series with one another between first node 110 and second node 112 with a first terminal of first capacitor 210₁ being connected to first node 110 and a second terminal of Nth capacitor 210_{N} being connected to second node 112.

In addition, and as shown in FIG. 4, feedback circuit 108 further includes a plurality of resistors, for example, a first resistor 212₁, a second resistor 212₂, . . . , and a Nth resistor 212_{N}. Each of the plurality of resistors are connected in a shunt configuration with an associated capacitor of the plurality of capacitors. For example, first resistor 212₁ is connected between a second terminal of first capacitor 210₁ and the ground. Similarly, second resistor 212₂ is connected between a second terminal of second capacitor 210₂ and the ground. Lastly, Nth resistor 212_{N} is connected between a second terminal of (N−1)th capacitor 210_{N-1} and the ground. Configuration of feedback circuit 108 of FIG. 4 may be used to improve a reliability of power amplifier 100. In some examples, a number of series capacitors with shunt resistors of feedback circuit 108 can be varied to vary an impedance of feedback circuit 108.

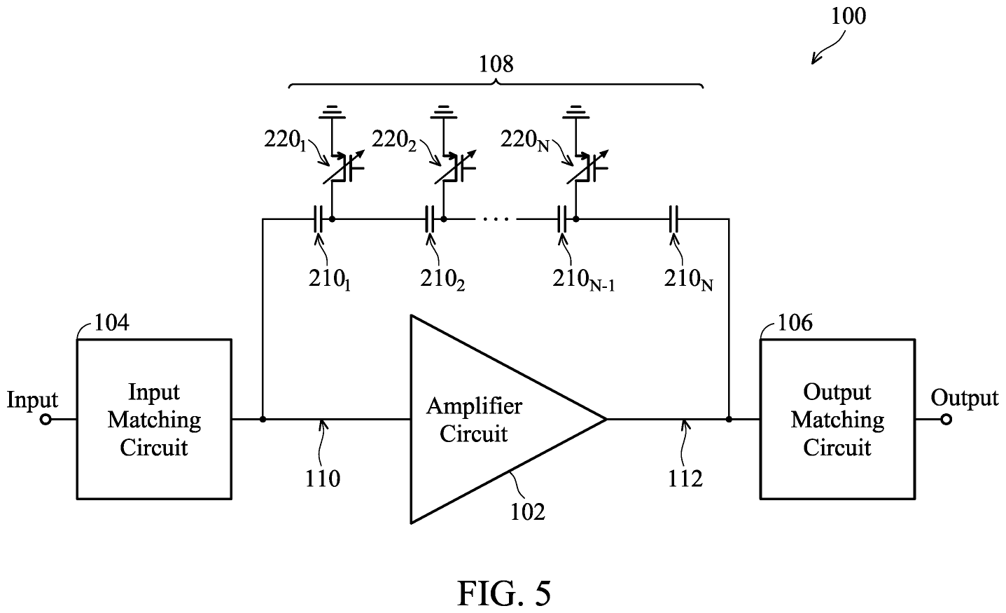

FIG. 5 is diagram of power amplifier 100 with feedback circuit 108 that includes series capacitors with shunt switches in accordance with some embodiments. As shown in FIG. 5, feedback circuit 108 includes a plurality of capacitors, for example, first capacitor 210₁, second capacitor 210₂, . . . , (N−1)th capacitor 210_{N-1}, and Nth capacitor 210_{N}. Each capacitor of the plurality of capacitors are connected in series with one another between first node 110 and second node 112 with the first terminal of first capacitor 210₁ being connected to first node 110 and the second terminal of Nth capacitor 210_{N} being connected to second node 112.

In addition, and as shown in FIG. 5, feedback circuit 108 further includes a plurality of switches, for example, a first switch 220₁, a second switch 220₂, . . . , and a Nth switch 220_{N}. Each of the plurality of switches are connected in a shunt configuration with an associated capacitor of the plurality of capacitors. For example, first switch 220₁ is connected between the second terminal of first capacitor 210₁ and the ground. Similarly, second switch 220₂ is connected between a second terminal of second capacitor 210₂ and the ground. Lastly, Nth switch 220_{N} is connected between a second terminal of (N−1)th capacitor 210_{N-1} and the ground. Each of the plurality of switches can be a semiconductor device, for example, a transistor. One of more switches of the plurality of switches of feedback circuit 108 of FIG. 5 can be switched on/off to match tuning of power amplifier 100. In some examples, a number of series capacitors with shunt switches of feedback circuit 108 can be varied to vary an impedance of feedback circuit 108.

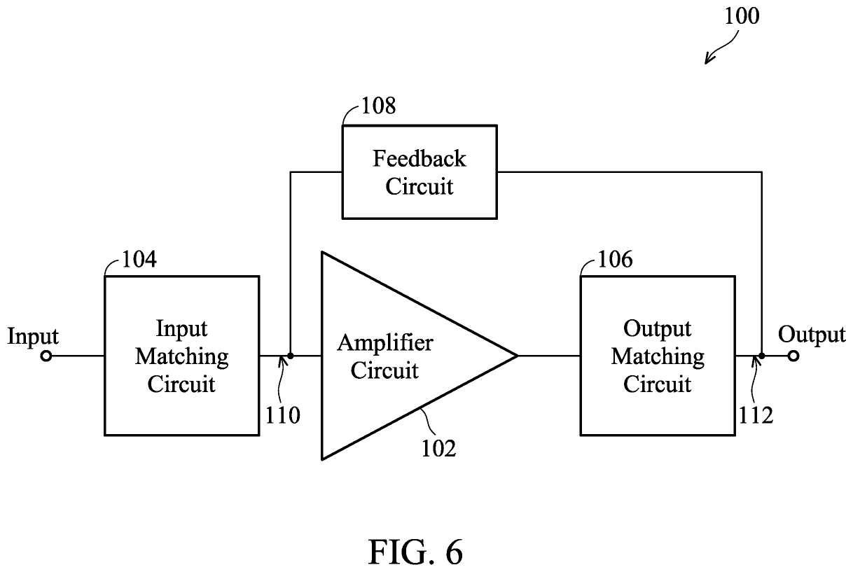

In accordance with example embodiments, although in FIGS. 1-5 feedback circuit 108 is shown to be connected between input and output nodes of amplifier circuit 102, feedback circuit 108 may be connected between any nodes of any elements of power amplifier 100. FIG. 6 is diagram illustrating power amplifier 100 with feedback circuit 108 connected between an output node of output matching circuit 106 and the input node of amplifier circuit 102. For example, and as shown in FIG. 6, the first terminal of feedback circuit 108 is connected to first node 110 (that is, the input node of amplifier circuit 102) and the second terminal of feedback circuit 108 is connected to the output terminal of output matching circuit 106 (that is, to the output node of output matching circuit 106.

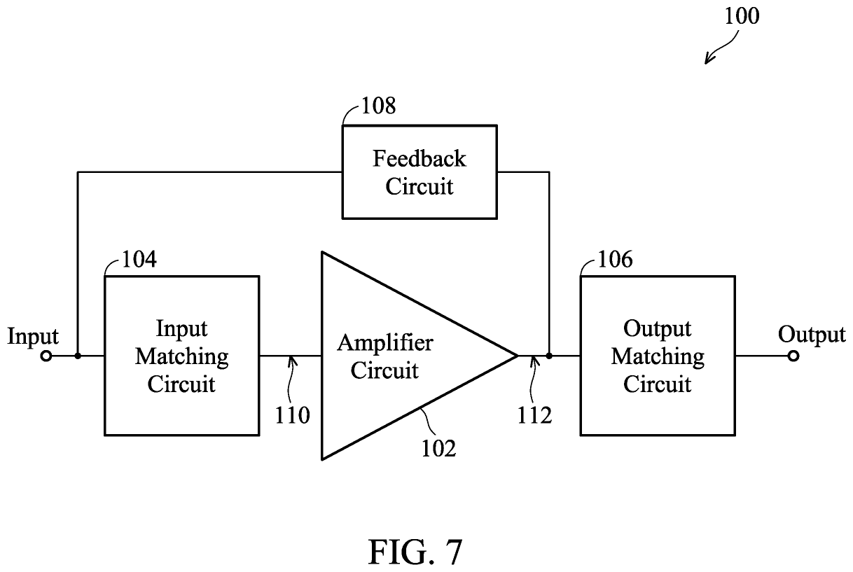

FIG. 7 is diagram illustrating power amplifier 100 with feedback circuit 108 connected between the output node of amplifier circuit 102 and an input node of input matching circuit 104. For example, and as shown in FIG. 7, the first terminal of feedback circuit 108 is connected to the first terminal of input matching circuit 104 (that is, the input node of input matching circuit 104) and the second terminal of feedback circuit 108 is connected to second node 112 (that is, the output node of amplifier circuit 102).

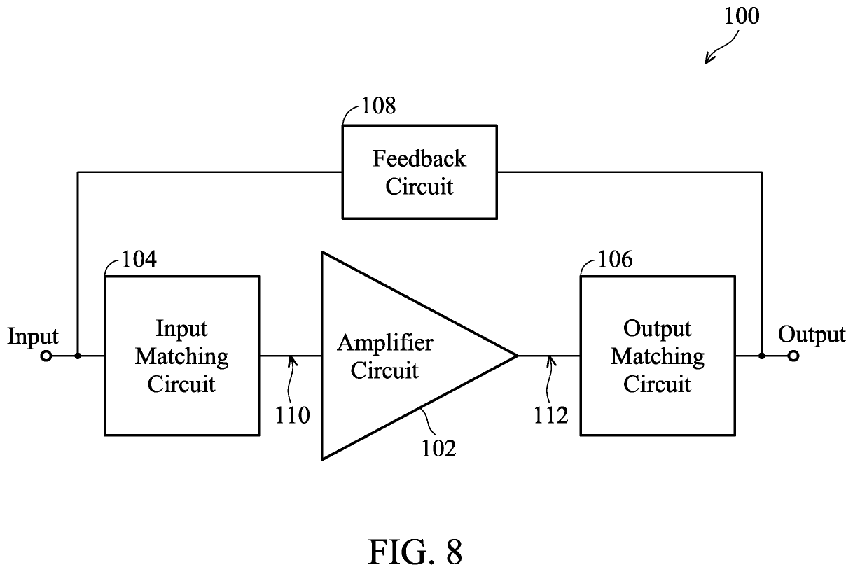

FIG. 8 is diagram illustrating power amplifier 100 with feedback circuit 108 connected between the output node of output matching circuit 106 and the input node of input matching circuit 104. For example, and as shown in FIG. 8, the first terminal of feedback circuit 108 is connected to the input terminal of input matching circuit 104 (that is, the input node of input matching circuit 104) and the second terminal of feedback circuit 108 is connected to the output terminal of output matching circuit 106 (that is, to the output node of output matching circuit 106.

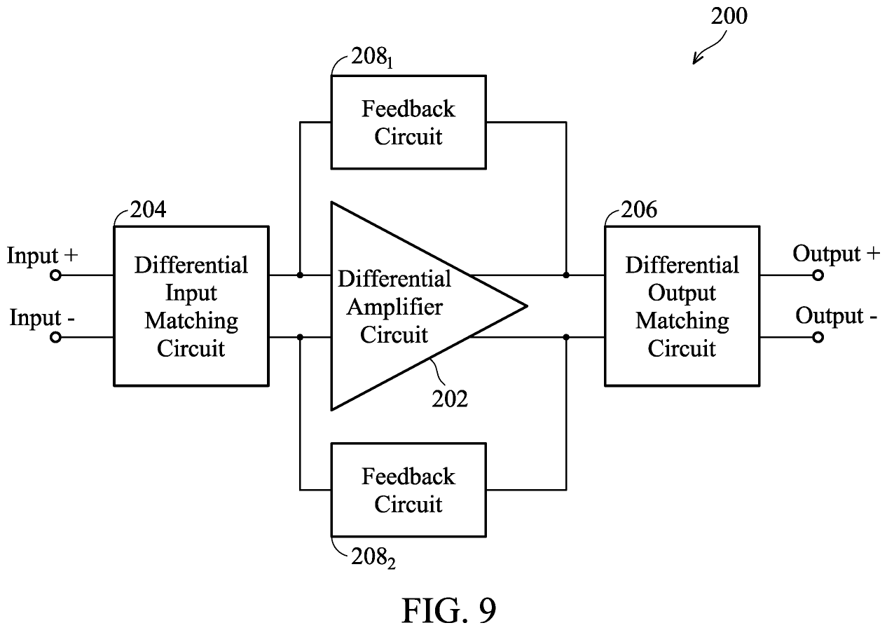

In accordance with example embodiments of the disclosure, feedback circuit 108 as discussed above with reference to FIGS. 3-8 may be employed in a differential amplifier. FIG. 9 is a diagram illustrating a differential power amplifier 200 with feedback circuits in accordance with some embodiments. Differential power amplifier 200 includes a first input terminal to receive a first input signal (denoted as input+) and a second input terminal to receive a second input signal (denoted as input-). Differential power amplifier 200 amplifies a difference between the first input signal and the second input signal and provides a first output signal at a first output terminal (denoted as output+) and a second output signal at a second output terminal (denoted as output-). In some example, differential power amplifier 200 differentially amplifies the input signal (that is, subtracts and multiplies). The output signals provided by differential power amplifier 200 have a higher power than the input signals.

Differential power amplifier 200 includes a differential amplifier circuit 202, a differential input matching circuit 204, and a differential output matching circuit 206. Differential power amplifier 200 further includes a first feedback circuit 208₁ and second feedback circuit 208₂.

Differential input matching circuit 204 matches an impedance of differential amplifier circuit 202 with an impedance of a source of the first and second input signals. Differential input matching circuit 204 also provides the first and second input signals received from one or more signal sources to input terminals of differential amplifier circuit. Differential input matching circuit 204 includes a first input terminal that is also the first input terminal of differential power amplifier 200 and a second input terminal that is also the second input terminal of differential power amplifier 200. Differential input matching circuit 204 further includes a first output terminal and a second output terminal. Differential input matching circuit 204 receives the first and second input signals at the first and second input terminals respectively and provides the first and second input signals at the first and second output terminals respectively. Differential input matching circuit 204 may function and be configured in a similar manner to input matching circuit 104 discussed above with reference to FIGS. 1-2.

Differential amplifier circuit 202 includes a first input terminal that is connected to the first output terminal of differential input matching circuit 204 and a second input terminal that is connected to the second output terminal of differential input matching circuit 204. Differential amplifier circuit 202 receives the first and second input signals at the first and second input terminals respectively from differential input matching circuit 204 and amplifies (for example, subtracts and multiplies) the first and second input signals to generate a first output signal and a second output signal. The first and second output signals are provided at the first and second output terminals respectively.

Differential output matching circuit 206 receives the first and second output signals from differential amplifier circuit 202 and provides the first and second output signals to one or more antennas or loads (not shown). In addition, differential output matching circuit 206 matches the impedance of differential amplifier circuit 202 with an impedance of the one or more antennas or loads. Differential output matching circuit 206 includes a first input terminal that is connected to the first output terminal of differential amplifier 202 and a second input terminal that is connected to the second output terminal of differential amplifier 202. Differential output matching circuit 206 may function and be configured in a similar manner to input matching circuit 104 discussed above with reference to FIGS. 1-2.

Differential input matching circuit 204 further includes a first output terminal that is also the first output terminal of differential power amplifier 200 and a second output terminal that is also the second output terminal of differential power amplifier 200. Differential output matching circuit 206 receives the first and second output signals at the first and second input terminals respectively from differential power amplifier 202 and provides the first and second output signals at the first and second output terminals respectively.

First feedback circuit 208₁ is connected between the first input terminal and the first output terminal of differential amplifier 202 while second feedback circuit 208₂ is connected between the second input terminal and the second output terminal of differential amplifier 202. For example, and as shown in FIG. 9, a first terminal of first feedback circuit 208₁ is connected to the first input terminal of differential amplifier 202 and a second terminal of first feedback circuit 208₁ is connected to the first output terminal of differential amplifier circuit 202. In addition, a first terminal of second feedback circuit 208₂ is connected to the second input terminal of differential amplifier 202 and a second terminal of second feedback circuit 208₁ is connected to the second output terminal of differential amplifier circuit 202.

First feedback circuit 208₁ and second feedback circuit 208₂ in combination improve functioning of differential power amplifier 200 in a same manner as feedback circuit 108 discussed above with reference to FIGS. 1-8. In addition, each of first feedback circuit 208₁ and second feedback circuit 208₂ may include one or more of an active element, a passive element, or a combination of an active and a passive element in a similar manner as feedback circuit 108 discussed with reference to FIGS. 2-8.

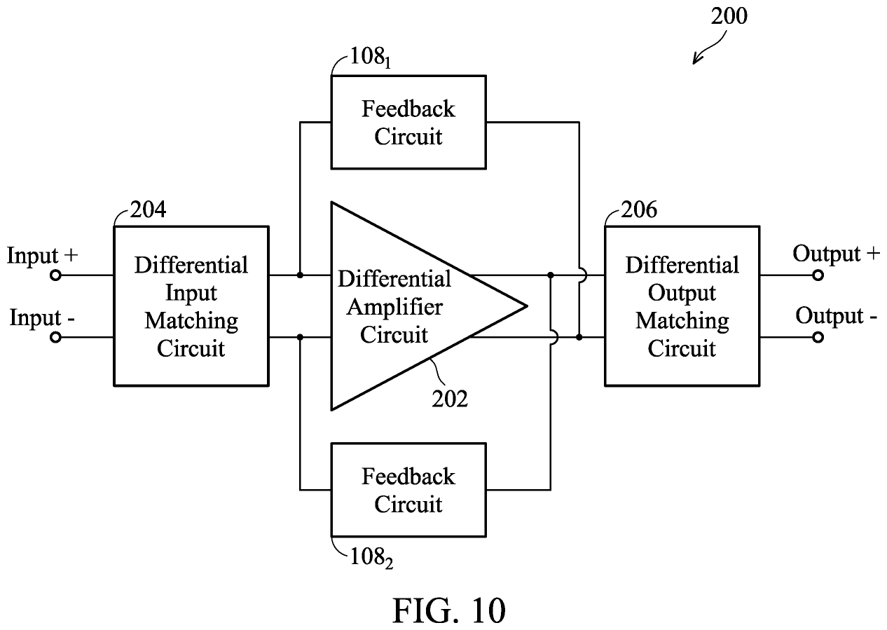

In some examples, feedback circuits of differential power amplifier 200 may be connected to provide differential feedbacks. FIG. 10 is a diagram illustrating differential power amplifier 200 with differential feedback circuits in accordance with some embodiments. As shown in FIG. 10, the first terminal of first feedback circuit 208₁ is connected to the first input terminal of differential amplifier 202 and the second terminal of first feedback circuit 208₁ is connected to the second output terminal of the differential amplifier 202. In addition, the first terminal of second feedback circuit 208₂ is connected to the second input terminal of differential amplifier circuit 202 and the second terminal of second feedback circuit 208₂ is connected to the first output terminal of differential amplifier 202.

Although the feedback circuits of differential power amplifier 200 have been shown to be connected between the output terminals and the input terminals of differential amplifier circuit 202 in FIGS. 9 and 10 but are not limited to such configuration. For example, and like configurations of feedback circuit 108 discussed above with reference to FIGS. 6-8, the feedback circuits of differential power amplifier 200 can be connected between any output terminals and any input terminals of any of differential amplifier circuit 202, differential input matching circuit 204, and differential output matching circuit 206.

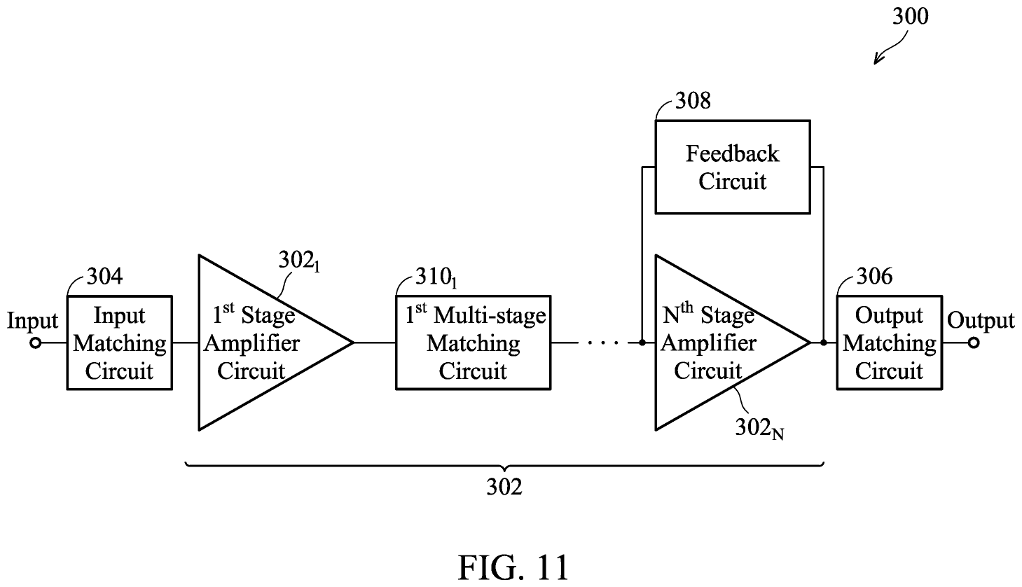

In accordance with some embodiments of the disclosure, feedback circuits my be provided to one or more stages of a multi-stage power amplifier. FIG. 11 illustrates a multi-stage power amplifier 300 with a single feedback circuit in accordance with some embodiments. As shown in FIG. 11, multi-stage power amplifier 300 includes a multi-stage amplifier circuit 302, an input matching circuit 304, and an output matching circuit 306. In addition, multi-stage power amplifier 300 may include a feedback circuit 308. Input matching circuit 304 may function and be configured similar to input matching circuit 104 described above with reference to FIGS. 1-8. Similarly, output matching circuit 306 may function and be configured similar to output matching circuit 106 described above with reference to FIGS. 1-8.

Multi-stage amplifier circuit 302 may include a plurality of stage amplifier circuits, for example, a first stage amplifier circuit 302₁, . . . , a Nth stage amplifier circuit 302_{N}. In addition, multi-stage amplifier circuit 302 includes a plurality of multi-stage matching circuits, for example, a first multi-stage matching circuit 310₁. Each of the plurality of stage amplifier circuits are connected in a series with each other with a multi-stage matching circuit between two consecutive stage amplifier circuits. For example, and as shown in FIG. 11, an input terminal of first stage amplifier circuit 302₁ is connected to an output terminal of input matching circuit 304. An output terminal of first stage amplifier circuit 302₁ is connected to an input terminal of first multi-stage matching circuit 310₁. An output terminal of first multi-stage matching circuit 310₁ is connected to an input terminal of a second stage amplifier circuit (not shown) and so on. Finally, an output terminal of Nth stage amplifier 302_{N} to an input terminal of output matching circuit 306.

In examples, each of multi-stage matching circuits may be a two-port circuit that connects two single stage amplifier circuits through coupling networks. Each of multi-stage matching circuits may minimize signal reflection and maximize power transfer between two single stage amplifiers connected on either side of the multi-stage matching circuit.

As shown in FIG. 11, feedback circuit 308 is connected between terminals of Nth stage amplifier circuit 302_{N} of multi-stage amplifier circuit 302. That is, a first terminal of feedback circuit 308 is connected to an input terminal of Nth stage amplifier circuit 302_{N} and an output terminal of feedback circuit 308 is connected to an output terminal of Nth stage amplifier circuit 302_{N}. Feedback circuit 308 may function and be configured similar to feedback circuit 108 discussed above with reference to FIGS. 1-8.

Although feedback circuit 308 is shown to connected across terminals of Nth stage amplifier circuit 302_{N} in FIG. 11, feedback circuit 308 can be connected across terminals of any of the plurality of stage amplifier circuits. In addition, although multi-stage power amplifier 300 of FIG. 11 is shown to include only one feedback circuit 308, multi-stage power amplifier 300 may include more than one feedback circuits each connected across terminals of any of the plurality of stage amplifier circuits or the plurality of multi-stage matching circuits.

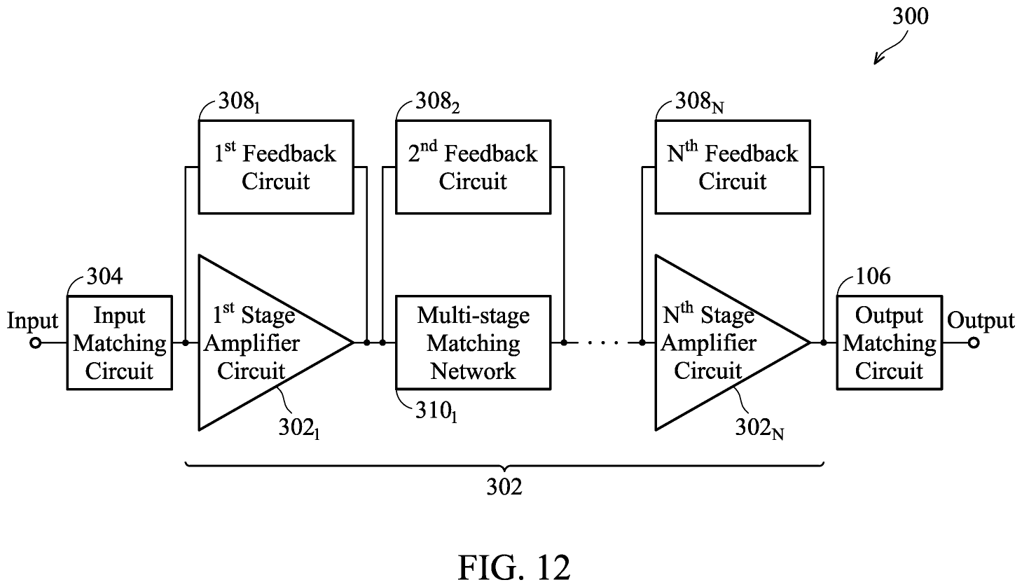

FIG. 12 is a diagram of multi-stage power amplifier 300 having multiple feedback circuits. For example, and as shown in FIG. 12, multi-stage power amplifier 300 includes a plurality of feedback circuits, that is, a first feedback circuit 308₁, a second feedback circuit 308₂, . . . , and a Nth feedback circuit 308_{N}. First feedback circuit 308₁ is connected to terminals of first stage amplifier circuit 302₁. That is, a first terminal of first feedback circuit 308₁ is connected to the input terminal of first stage amplifier circuit 302₁ and a second terminal of first feedback circuit 308₁ is connected to the output terminal of first stage amplifier circuit 302₁. Similarly, second feedback circuit 308₂ is connected to terminals of first multi-stage matching network 310₁. That is, a first terminal of second feedback circuit 308₂ is connected to the input terminal of first multi-stage matching network 310₁ and a second terminal of second feedback circuit 308₂ is connected to the output terminal of first multi-stage network 310₁. Lastly, Nth feedback circuit 308_{N} is connected to terminals of Nth stage amplifier circuit 302_{N}. That is, a first terminal of Nth feedback circuit 308_{N} is connected to the input terminal of Nth stage amplifier circuit 302_{N} and a second terminal of Nth feedback circuit 308_{N} is connected to the output terminal of Nth stage amplifier circuit 302_{N}.

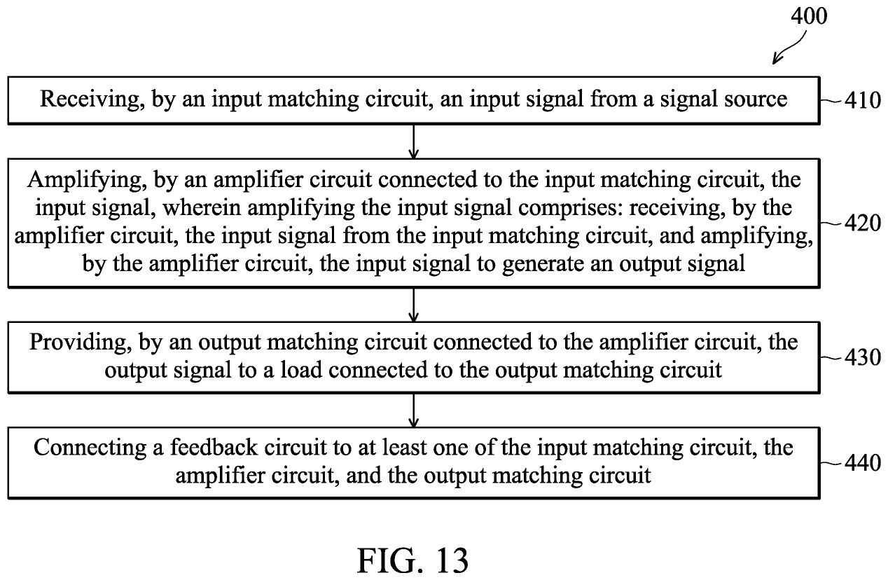

FIG. 13 is a flow diagram of a method 400 for amplifying an input signal in accordance with some embodiments. Although, method 400 is being described with reference to power amplifier 100, it may be performed using differential power amplifier 200 and multi-stage power amplifier 300.

At block 410 of method 400 input matching circuit 104 receives an input signal from a signal source. The input signal may be a radio frequency signal having a first power. The input signal is received at the input terminal of input matching circuit 104.

At block 420 of method 400, amplifier circuit 102 that is connected to input matching circuit 104 amplifies the input signal. In some examples, amplifying the input signal may include receiving, by amplifier circuit 102, the input signal from input matching circuit and amplifying, by amplifier circuit 102, the input signal to generate an output signal. In some examples, a signal power of the output signal is greater than the input signal. The ratio between the signal power of the input signal and the output signal may depend on amplifier circuit 102. In some examples, amplifier circuit 102 can be programed to amplify the signal power of the input signal by a predetermined value to produce the output signal.

At block 430 of method 400, output matching circuit 106 provides the output signal to a load connected to output matching circuit 106. As discussed above, an input terminal of output matching circuit 106 is connected to an output terminal of amplifier circuit 102 and receives the output signal from amplifier circuit 102. Output matching circuit 106 provides the output signal to the load through its output terminal that is connected to the load.

At block 440 of method 400, feedback circuit 108 is connected to at least one of input matching circuit 104, amplifier circuit 102, and output matching circuit 106. Feedback circuit 108 is configured to assist in matching the first impedance of the amplifier circuit with the second impedance of the load match and matching the first impedance of the amplifier circuit with a third impedance of the signal source. For example, feedback circuit 108 when connected in parallel to amplifier circuit 102 may alter an impedance of amplifier circuit 102 to match with an impedance of a load connected to an output of output matching circuit 106 and/or with an impedance of a signal source connected to input matching circuit 104. The impedance of feedback circuit 108 can be varied based on impedances of the signal source and the load.

In accordance with example embodiments, a power amplifier comprises: an input matching circuit configured to receive an input signal from a signal source; an amplifier circuit connected to the input matching circuit, wherein the amplifier circuit is configured to: receive the input signal from the input matching circuit, and amplify the input signal to generate an output signal; an output matching circuit connected to the amplifier circuit, wherein the output matching circuit is configured to receive the output signal from the amplifier circuit and provide the output signal to a load connected to the output matching circuit, and wherein the output matching circuit is further configured to match a first impedance of the amplifier circuit with a second impedance of the load; and a feedback circuit connected to at least one or the input matching circuit, the amplifier circuit, and the output matching circuit, wherein the feedback circuit is configured to assist in at least one of the following: matching the first impedance of the amplifier circuit with the second impedance of the load, and matching the first impedance of the amplifier circuit with a third impedance of the signal source.

In example embodiments of the disclosure, a differential power amplifier comprises: a differential input matching circuit configured to receive a first input signal and a second input signal from one or more signal sources; a differential amplifier circuit connected to the differential input matching circuit, wherein the differential amplifier circuit is configured to: receive the first input signal and the second input signal from the differential input matching circuit, and amplify a difference between the first input signal and the second input signal to generate a first output signal and a second output signal; a differential output matching circuit connected to the differential amplifier circuit, wherein the differential output matching circuit is configured to receive the first output signal and the second output signal from the differential amplifier circuit and provide the first output signal and the second output signal to one or more load connected to the differential output matching circuit, and wherein the differential output matching circuit is further configured to match a first impedance of the differential amplifier circuit with a second impedance of the one or more load; and at least two feedback circuits connected to at least one or the differential input matching circuit, the differential amplifier circuit, and the differential output matching circuit, wherein the at least two feedback circuits are configured to assist in at least one of the following: matching the first impedance of the differential amplifier circuit with the second impedance of the load, and matching the first impedance of the differential amplifier circuit with a third impedance of the one or more signal source.

In accordance with example embodiments, a method of amplifying an input signal, comprises: receiving, by an input matching circuit, an input signal from a signal source; amplifying, by an amplifier circuit connected to the input matching circuit, the input signal, wherein amplifying the input signal comprises: receiving, by the amplifier circuit, the input signal from the input matching circuit, and amplifying, by the amplifier circuit, the input signal to generate an output signal; providing, by an output matching circuit connected to the amplifier circuit, the output signal to a load connected to the output matching circuit, wherein the output matching circuit is configured to match a first impedance of the amplifier circuit with a second impedance of the load; and connecting a feedback circuit to at least one of the input matching circuit, the amplifier circuit, and the output matching circuit, wherein the feedback circuit is configured to assist in at least one of the following: matching the first impedance of the amplifier circuit with the second impedance of the load match, and matching the first impedance of the amplifier circuit with a third impedance of the signal source.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A power amplifier comprising:
an input matching circuit configured to receive an input signal from a signal source;
an amplifier circuit connected to the input matching circuit, wherein the amplifier circuit is configured to:
receive the input signal from the input matching circuit, and
amplify the input signal to generate an output signal,
an output matching circuit connected to the amplifier circuit, wherein the output matching circuit is configured to receive the output signal from the amplifier circuit and provide the output signal to a load connected to the output matching circuit, and wherein the output matching circuit is further configured to match a first impedance of the amplifier circuit with a second impedance of the load; and
a feedback circuit connected to at least one of the input matching circuit, the amplifier circuit, and the output matching circuit, wherein the feedback circuit is operable to assist in at least one of the following:
matching the first impedance of the amplifier circuit with the second impedance of the load match, and
matching the first impedance of the amplifier circuit with a third impedance of the signal source.

2. The power amplifier of claim 1, wherein the output signal has a higher power than the input signal.

3. The power amplifier of claim 1, wherein the feedback circuit is connected across terminals of the amplifier circuit.

4. The power amplifier of claim 1, wherein the feedback circuit comprises an energy storage device.

5. The power amplifier of claim 1, wherein the feedback circuit comprises a plurality of transmission lines.

6. The power amplifier of claim 1, wherein the feedback circuit comprises a plurality of capacitors connected in series and a plurality of shunt resistors.

7. The power amplifier of claim 1, wherein the feedback circuit comprises a plurality of capacitors connected in series and a plurality of shunt switches.

8. The power amplifier of claim 1, wherein the feedback circuit is connected between an output terminal of the amplifier circuit and an input terminal of the input matching circuit.

9. The power amplifier of claim 1, wherein the feedback circuit is connected between an output terminal of the output matching circuit and an input terminal of the amplifier circuit.

10. The power amplifier of claim 1, wherein the feedback circuit is connected between an output terminal of the output matching circuit and an input terminal of the input matching circuit.

11. The power amplifier of claim 1, wherein the amplifier circuit comprises a transistor.

12. A differential power amplifier, comprising:
a differential input matching circuit configured to receive a first input signal and a second input signal from one or more signal sources;
a differential amplifier circuit connected to the differential input matching circuit, wherein the differential amplifier circuit is configured to:
receive the first input signal and the second input signal from the differential input matching circuit, and
amplify a difference between the first input signal and the second input signal to generate a first output signal and a second output signal;
a differential output matching circuit connected to the differential amplifier circuit, wherein the differential output matching circuit is configured to receive the first output signal and the second output signal from the differential amplifier circuit and provide the first output signal and the second output signal to one or more load connected to the differential output matching circuit, and wherein the differential output matching circuit is further configured to match a first impedance of the differential amplifier circuit with a second impedance of the one or more load; and
at least two feedback circuits connected to at least one or the differential input matching circuit, the differential amplifier circuit, and the differential output matching circuit, wherein the at least two feedback circuits are configured to assist in at least one of the following:
matching the first impedance of the differential amplifier circuit with the second impedance of the one or more load, and
matching the first impedance of the differential amplifier circuit with a third impedance of the one or more signal sources.

13. The differential power amplifier of claim 12, wherein a first feedback circuit of the at least two feedback circuits is connected between a first output terminal and a first input terminal of the differential amplifier circuit, and wherein a second feedback circuit of the at least two feedback circuits is connected between a second output terminal and a second input terminal of the differential amplifier circuit.

14. The differential power amplifier of claim 12, wherein a first feedback circuit of the at least two feedback circuits is connected between a second output terminal and a first input terminal of the differential amplifier circuit, and wherein a second feedback circuit of the at least two feedback circuits is connected between a first output terminal and a second input terminal of the differential amplifier circuit.

15. The differential power amplifier of claim 12, wherein each of the at least two feedback circuits comprises at least one passive element.

16. The differential power amplifier of claim 12, wherein each of the at least two feedback circuits comprises at least one active element.

17. A method of amplifying an input signal, the method comprising:
receiving, by an input matching circuit, an input signal from a signal source;
amplifying, by an amplifier circuit connected to the input matching circuit, the input signal, wherein amplifying the input signal comprises:
receiving, by the amplifier circuit, the input signal from the input matching circuit,
amplifying, by the amplifier circuit, the input signal to generate an output signal;
providing, by an output matching circuit connected to the amplifier circuit, the output signal to a load connected to the output matching circuit, wherein the output matching circuit is configured to match a first impedance of the amplifier circuit with a second impedance of the load;
connecting a feedback circuit to at least one of the input matching circuit, the amplifier circuit, and the output matching circuit, wherein the feedback circuit is configured to assist in at least one of the following:
matching the first impedance of the amplifier circuit with the second impedance of the load, and
matching the first impedance of the amplifier circuit with a third impedance of the signal source.

18. The method of claim 17, wherein amplifying, by the amplifier circuit, the input signal to generate the output signal comprises amplifying, by the amplifier circuit, the input signal to generate the output signal having a higher power than the input signal.

19. The method of claim 17, wherein feedback circuit comprises at least one of the following: at least one active element, at least one passive element, and at combination of at least one active element and at least one passive element.

20. The method of claim 17, wherein the feedback circuit comprises an energy storage element.
